(19) United States
(12) Patent Application Publication
(10) Pub. No.: US 2022/0416751 A1
(43) Pub. Date: Dec. 29, 2022

(54) IMPEDANCE MATCHING CIRCUIT AND AN IMPEDANCE MATCHING ELEMENT

(71) Applicant: Intel Corporation, Santa Clara, CA (US)

(72) Inventors: Ritesh A. BHAT, Hillsboro, OR (US); Woorim SHIN, Portland, OR (US)

(21) Appl. No.: 17/356,530

(22) Filed: Jun. 24, 2021

(51) Int. Cl. H03H 7/38; H03H 7/42

(52) U.S. Cl. CPC H03H 7/38; H03H 7/42

(57) ABSTRACT

Impedance matching circuits, impedance matching elements, and radio communication circuits are provided in this disclosure. The impedance matching circuit may include a first impedance matching element which is configured to radio communication circuit may include a modulator configured to receive an unbalanced input signal from a first input, and couple the unbalanced input signal to a first output to match an impedance of the first output to a first impedance. It may further include a second impedance matching element coupled to the first input to receive the unbalanced input signal, the second impedance matching element configured to couple the unbalanced input signal to a second output to match an impedance of the second output to a second impedance. A terminal of the first output and a terminal of the second output may be coupled to provide a balanced output signal, and the coupling may match an output impedance of the impedance matching circuit based on the first impedance and the second impedance.

### TECHNICAL FIELD

This disclosure generally relates to an impedance matching circuit, an impedance matching element, and a radio communication circuit.

### BACKGROUND

Radio communication devices may include radio communication circuits that may include various circuits and components. While some of these components and/or circuits may be configured to operate with balanced signals (e.g. amplifiers), other components and/or circuits may be configured to operate with unbalanced signals (e.g. antennas). It is desirable to provide conversion between a balanced signal and an unbalanced signal. Traditionally, radio communication devices include baluns to provide conversion between balanced signals and unbalanced signals.

In communications, and also in other electronic devices, it may be desirable to match the impedance of a signal source that provides a signal to a load which may be another component or circuit. For example, it may be desirable to match the impedance of a power amplifier to an antenna in a radio communication circuit in order to reduce the risk of reflection of the signal provided by the power amplifier to the antenna.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 shows schematically a block diagram of an example of a radio communication device;

FIG. 2 shows schematically a block diagram of an example radio frequency (RF) front end;

FIG. 3 shows schematically an example of a radio communication circuit;

FIG. 4 shows schematically a block diagram of an exemplary radio communication device or system;

FIG. 5 shows schematically an example of an input of a low noise amplifier in a radio communication circuit;

FIG. 6 shows schematically an example of a balun;

FIG. 7 shows schematically an example of an impedance matching circuit;

FIG. 8A shows schematically a diagram for a coupled-line balun having coupled lines with the same line lengths;

FIG. 8B shows schematically a diagram for a coupled-line balun having coupled lines with different line lengths;

FIG. 8C shows schematically a diagram for a coupled-line balun having coupled lines with different line lengths;

FIG. 9 shows schematically a diagram for certain characteristics of a coupled-line balun provided and a 1:4 transformer based balun;

FIG. 10 shows schematically an example of an impedance matching circuit including a transformer;

FIG. 11 shows schematically an example of an impedance matching circuit;

FIG. 12 shows schematically an example of an impedance matching circuit;

FIG. 13 shows schematically an example of an impedance matching circuit.

### DESCRIPTION

The following detailed description refers to the accompanying drawings that show, by way of illustration, exemplary details and aspects in which aspects of the present disclosure may be practiced.

One of the traditional methods used to provide conversion between balanced signals and unbalanced signals in a radio communication circuit includes using coil-based transformers. Coil-based transformers may provide compact solutions that further may provide DC isolation between the input terminals and output terminals of the coil-based transformer. This allows different biasing voltages to be used for the stages that precede and succeed these networks.

Moreover, especially for power amplifiers and low noise amplifiers that are used in a radio communication circuit, resulting galvanic isolation has electro-static discharge protection benefits. Marchand baluns and sleeve baluns may also be employed when the radio communication circuit is configured to operate at mmWave and sub-THz frequencies as matching networks. Guanella baluns may also be used to obtain 1:4 impedance transformation ratios.

With the recent implementation of communication techniques to support increases in data traffic, radio communication devices need to support radio communication signals at higher frequencies with wider bandwidths (BW) and higher-order modulations schemes. Furthermore, due to the advancement in communication technologies, e.g. wireless communication technology, and also semiconductor technology, and the motivation to provide devices having smaller form factor to the market, smaller radio communication devices may be provided for various reasons.

In order to support radio communication signals at higher frequencies with wider bandwidths, a radio communication circuit may require impedance matching elements that may provide a more consistent matching with higher impedance transformation ratios. This may be obtained in coil-based baluns by using more distant turn ratios which may result in lower self-resonance frequencies (SRF) and higher losses. Typically, at sub-THz frequencies, for a fully integrated balun, a 1:1 turns ratio may provide the optimum loss and SRF. This 1:1 turns ratio can only provide limited impedance transformation ratios. Another technique may be to reduce the coupling coefficient (k) of the transformer.

Alternatively, Marchand baluns and/or sleeve baluns may be used for matching impedances having mainly real components for broadband signals, however, it may be desirable to match complex impedances especially for power amplifiers and low noise amplifiers having complex impedances that may be conjugately matched over a wide range of frequencies. The employment of additional passives matchings may further result in resonation of the imaginary component of impedances. Such resonation may cause further losses and may introduce challenges with respect to bandwidth. Accordingly, it may be desirable to provide an impedance matching circuit to address at least one of these challenges.

The following detailed description refers to the accompanying drawings that show, by way of illustration, specific details and aspects in which the disclosure may be practiced.

The word “exemplary” is used herein to mean “serving as an example, instance, or illustration”. Any aspect or design described herein as “exemplary” is not necessarily to be construed as preferred or advantageous over other aspects or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one. The terms “proper subset”, “reduced subset”, and “lesser subset” refer to a subset of a set that is not equal to the set, i.e. a subset of a set that contains fewer elements than the set.

The term “amplifier” utilized herein refers to any type of component, circuit, module, or device which amplifies (i.e. increase power/amplitude) an input signal and may provide an amplified signal as an output signal. The amplifier may be any type of amplifier, an amplifier stack, or an amplifier stage.

As used herein, “memory” is understood as a non-transitory computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

The term “radio communication device” utilized herein refers to any devices using radio frequency signals for communication including user-side devices (both portable and fixed) that can connect to a core network and/or external data networks via a radio access network. “Radio communication device” can include any mobile or immobile wireless communication device, including User Equipment (UEs), Mobile Stations (MSs), Stations (STAs), cellular phones, tablets, laptops, personal computers, wearables, multimedia playback, and other handheld or body-mounted electronic devices, consumer/home/office/commercial appliances, vehicles, and any other electronic device capable of user-side wireless communications. Without loss of generality, in some cases terminal devices can also include application-layer components, such as application processors or other general processing components that are directed to functionality other than wireless communications. Radio communication devices can optionally support wired communications in addition to wireless communications. Furthermore, radio communication devices can include vehicular communication devices that function as radio communication devices. The term “radio communication circuit” may refer to a circuit of a radio communication device.

Various aspects of this disclosure may utilize or be related to radio communication technologies. While some examples may refer to specific radio communication technologies, the examples provided herein may be similarly applied to various other radio communication technologies, both existing and not yet formulated, particularly in cases where such radio communication technologies share similar features as disclosed regarding the following examples. As used herein, a first radio communication technology may be different from a second radio communication technology if the first and second radio communication technologies are based on different communication standards.

Aspects described herein may use such radio communication technologies according to various spectrum management schemes, including, but not limited to, dedicated licensed spectrum, unlicensed spectrum, (licensed) shared spectrum (such as LSA, “Licensed Shared Access,” in 2.3-2.4 GHz, 3.4-3.6 GHz, 3.6-3.8 GHz and further frequencies and SAS, “Spectrum Access System,” in 3.55-3.7 GHz and further frequencies), and may be use various spectrum bands including, but not limited to, IMT (International Mobile Telecommunications) spectrum (including 450-470 MHz, 790-960 MHz, 1710-2025 MHz, 2110-2200 MHz, 2300-2400 MHz, 2500-2690 MHz, 698-790 MHz, 610-790 MHz, 3400-3600 MHz, etc., where some bands may be limited to specific region(s) and/or countries), IMT-advanced spectrum, IMT-2020 spectrum (expected to include 3600-3800 MHz, 3.5 GHz bands, 700 MHz bands, bands within the 24.25-86 GHz range, etc.), spectrum made available under FCC's “Spectrum Frontier” 5G initiative (including 27.5-28.35 GHz, 29.1-29.25 GHz, 31-31.3 GHz, 37-38.6 GHz, 38.6-40 GHz, 42-42.5 GHz, 57-64 GHz, 64-71 GHz, 71-76 GHz, 81-86 GHz and 92-94 GHz, etc.), the ITS (Intelligent Transport Systems) band of 5.9 GHz (typically 5.85-5.925 GHz) and 63-64 GHz, bands currently allocated to WiGig such as WiGig Band 1 (57.24-59.40 GHz), WiGig Band 2 (59.40-61.56 GHz) and WiGig Band 3 (61.56-63.72 GHz) and WiGig Band 4 (63.72-65.88 GHz), the 70.2 GHz-71 GHz band, any band between 65.88 GHz and 71 GHz, bands currently allocated to automotive radar applications such as 76-81 GHz, and future bands including 94-300 GHz and above.

For purposes of this disclosure, radio communication technologies may be classified as one of a Short-Range radio communication technology or Cellular Wide Area radio communication technology. Short Range radio communication technologies may include Bluetooth, WLAN (e.g., according to any IEEE 802.11 standard), and other similar radio communication technologies. Cellular Wide Area radio communication technologies may include Global System for Mobile Communications (GSM), Code Division Multiple Access 2000 (CDMA2000), Universal Mobile Telecommunications System (UMTS), Long Term Evolution (LTE), General Packet Radio Service (GPRS), Evolution-Data Optimized (EV-DO), Enhanced Data Rates for GSM Evolution (EDGE), High Speed Packet Access (HSPA; including High Speed Downlink Packet Access (HSDPA), High Speed Uplink Packet Access (HSUPA), HSDPA Plus (HSDPA+), and HSUPA Plus (HSUPA+)), Worldwide Interoperability for Microwave Access (WiMax) (e.g., according to an IEEE 802.16 radio communication standard, e.g., WiMax fixed or WiMax mobile), etc., and other similar radio communication technologies. Cellular Wide Area radio communication technologies also include “small cells” of such technologies, such as microcells, femtocells, and picocells. Cellular Wide Area radio communication technologies may be generally referred to herein as “cellular” communication technologies.

The terms “radio communication network,” “wireless network”, “communication network,” or the like, as utilized herein encompasses both an access section of a network (e.g., a radio access network (RAN) section) and a core section of a network (e.g., a core network section).

The term “balun” utilized herein refers to any circuits or components that are configured to provide a conversion between a balanced signal and an unbalanced signal. Baluns may be any type of baluns, including transformer type baluns including at least one transformer, transmission line baluns including a transmission line or a coupled line, and delay line baluns. It should be further considered that baluns have inputs in context, e.g. whether the desired conversion is from unbalanced signal to balanced signal, or from balanced signal to unbalanced signal.

Unless explicitly specified, the term “transmit” encompasses both direct (point-to-point) and indirect transmission (via one or more intermediary points). Similarly, the term “receive” encompasses both direct and indirect reception. Furthermore, the terms “transmit”, “receive”, “communicate”, and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as radio frequency (RF) transceivers and antennas, and the logical transmission and reception over the software-level connection is performed by the processors or controllers. The term “communicate” may encompass one or both of transmitting and receiving, i.e., unidirectional or bidirectional communication in one or both of the incoming and outgoing directions. The term “calculate” may encompass both ‘direct’ calculations via a mathematical expression/formula/relationship and ‘indirect’ calculations via lookup or hash tables and other array indexing or searching operations.

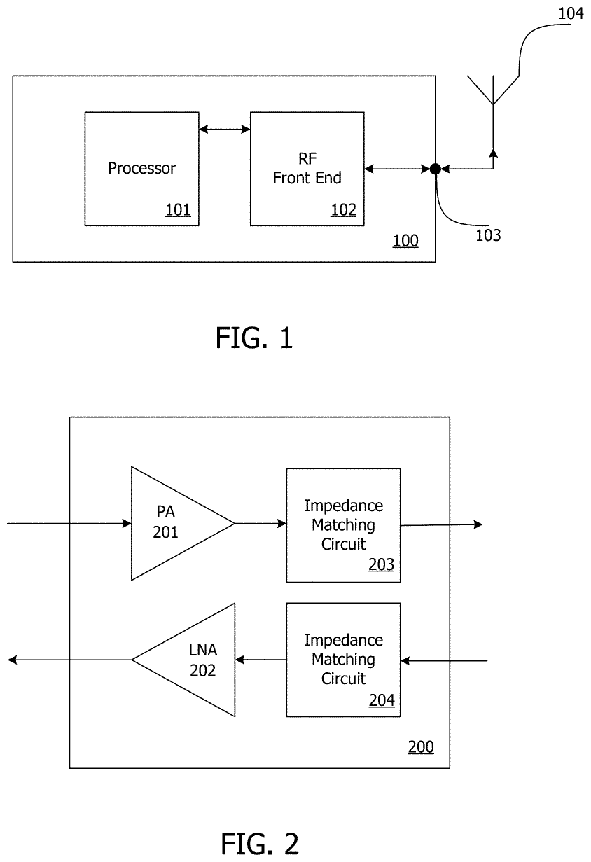

FIG. 1 shows schematically a block diagram of an example of a radio communication device 100. The radio communication device 100 includes a processor 101. A radio frequency (RF) front end 102 is coupled to the processor 101 and an antenna port 103. The antenna port 103 may be coupled to an antenna 104. The communication device 100 may include a plurality of processors, a plurality of radio frequency (RF) front ends, a plurality of antenna ports, and a plurality of antennas.

For transmitting function, the processor 101 provides signals to be transmitted to the radio frequency (RF) front end 102. The radio frequency (RF) front end 102 may receive the signals from the processor 101. The radio frequency (RF) front end 102 provides the radio frequency (RF) communication signals to the antenna port 103 so that the antenna 104 receives the radio frequency (RF) communication signals from the antenna port 103 and transmits the radio communication signals. The radio frequency (RF) front end 102 may include an upconverter to convert received signals to the radio frequency (RF) communication signals. The radio frequency (RF) front end 102 may include a power amplifier.

For receiving function, the antenna port 103 receives radio frequency (RF) communication signals from the antenna 104. The radio frequency (RF) front end 102 receives the radio frequency (RF) communication signals from the antenna port 103. The radio frequency (RF) front end may 102 include a downconverter to convert the radio frequency (RF) communication signals. The radio frequency (RF) front end 102 provides its output to the processor 101 which may receive baseband communication signals and decode the baseband communication signals.

The radio communication device 100 is only provided as an example of a radio communication device capable of performing both a transmitting function and a receiving function. A radio communication device may exemplarily be capable of performing only one of these functions (i.e. as a receiver or transmitter), and various aspects provided with this disclosure may apply in these examples as well.

The radio communication device 100 may communicate with a radio communication network, or other radio communication devices and/or network access nodes. Although the communication may take place in compliant with certain examples described herein which refer to a particular radio access network context (e.g., WLAN/WiFi, 5G, NR, LTE, or other 3rd Generation Partnership Project (3GPP) networks, Bluetooth, mmWave, etc.), these examples are demonstrative and may therefore be readily applied to any other type or configuration of radio access network.

FIG. 2 shows schematically a block diagram of an example radio frequency (RF) front end 200 that may be implemented in a radio communication device including a transmitter and a receiver. A transmit signal path (Tx path) of the radio frequency (RF) front end 200 includes a PA (power amplifier) 201 for amplifying input radio frequency (RF) signals and an impedance matching circuit 203 configured to match the output impedance of the power amplifier 201 with an input impedance of a further component, such as an antenna.

A receive signal path (Rx path) of the radio frequency (RF) front end 200 includes an LNA (low-noise amplifier) 202 to amplify received radio frequency (RF) signals and provides the amplified received radio frequency (RF) signals as an output, and an impedance matching circuit 204 configured to match the input impedance of the low-noise amplifier with a further component, such as an antenna, that provided the radio frequency (RF) signals. One or more filters may be included to generate suitable radio frequency (RF) signals for transmission and reception. In addition, the radio frequency (RF) front end 200 may include other components or circuits 203, such as, for example, a tuner, switches, multiplexers, and/or other circuits for coupling the radio frequency (RF) front end 200 to an antenna. In addition, other components may be included to support both transmit and receive functions.

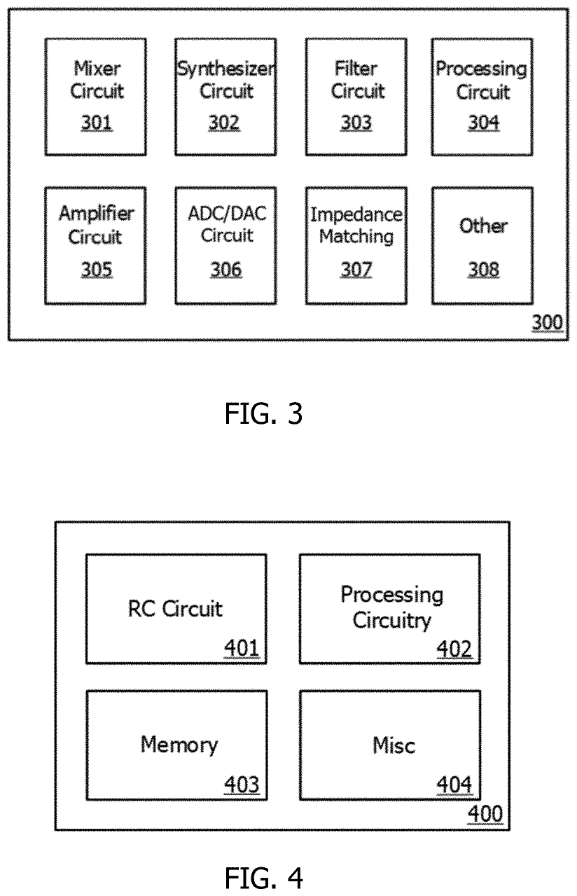

FIG. 3 shows schematically an example of a radio communication circuit 300 which a radio communication device may include. The radio communication circuit 300 can include components such as a mixer circuit 301, a synthesizer circuit 302 (e.g., local oscillator), a filter circuit 303 (e.g., baseband filter), a processing circuit 304, an amplifier circuit 305, an analog-to-digital converter (ADC) and/or a digital-to analog (DAC) circuit 306, an impedance matching circuit 307, other suitable digital front end (DFE) components 308, and impedance matching circuits, to name a few. The processing circuit 304 may include a processor, which in turn may include a time-domain and/or frequency domain processor(s)/components in at least one example.

Accordingly, the exemplary radio frequency (RF) front end 200 referred with respect to FIG. 2 may be provided by a combination of the circuits provided with respect to the schematic representation of the example of the radio communication circuit 300. It should be noted that any of these circuits may include a plurality of circuits configured to provide the functionality. For example, the amplifier circuit 305 may include a plurality of amplifier circuits or amplifiers.

The other components 308 may include logic components, modulation/demodulation elements, and an interface circuit for interfacing with another component, e.g., an SoC, or a modem. Digital front end components may include any suitable number and/or type of components configured to perform functions known to be associated with digital front ends.

The digital front end may include digital processing circuit, portions of processing circuitry, one or more portions of an on-board chip having dedicated digital front end functionality (e.g., a digital signal processor), etc. The digital front end components may selectively perform specific functions based upon the operating mode of the radio communication circuit 300. The digital front end components may facilitate beamforming.

Digital front end components may also include other components associated with data transmission such as, for instance, transmitter impairment correction such as LO correction, DC offset correction, IQ imbalance correction, and ADC skew, digital pre-distortion (DPD) calculation, correction factor (CF) calculation, and pre-emphasis (pre. emp.) calculation. To provide additional examples, the digital front end components may facilitate or perform receiver or transmitter digital gain control (DGC), up-sampling, down-sampling, zero crossing detection algorithms, phase modulation, perform beam management, digital blocker cancellation, received signal strength indicator (RSSI) measurements, DPD and calibration accelerators, test signal generation, etc.

The radio communication circuit 300 may include a receive signal path which may include the mixer circuit 301, the amplifier circuit 305, and the filter circuit 303. The transmit signal path of the radio communication circuit 300 may include the filter circuit 303, the amplifier circuit 305, and the mixer circuit 301. The radio communication circuit may also include the synthesizer circuit 302 to synthesize a frequency signal for use by the mixer circuit 301 of the receive signal path and the transmit signal path. The mixer circuit 301 of the receive signal path may be configured to down-convert radio frequency (RF) signals received based on the synthesized frequency provided by synthesizer circuit 302.

The output baseband signals and the input baseband signals may be digital baseband signals. The radio communication circuit 300 may include the analog-to-digital converter (ADC) circuit and the digital-to-analog converter (DAC) circuit 306.

The radio communication circuit 300 may also include a transmit signal path (Tx path) which may include a circuit to up-convert baseband signals provided by a modem and provide radio frequency (RF) output signals for transmission. The receive signal path of the radio communication circuit 300 may include the mixer circuit 301, the amplifier circuit 305, and the filter circuit 303. The transmit signal path of the radio communication circuit 300 may include the filter circuit 303, the amplifier circuit 305, and the mixer circuit 301. The radio communication circuit 300 may include synthesizer circuit 302 to synthesize a frequency signal for use by the mixer circuit 301 of the receive signal path and the transmit signal path. The mixer circuit 301 of the receive signal path may be configured to received down-convert radio frequency (RF) signals based on the synthesized frequency provided by synthesizer circuit 302.

Amplifier circuit 305 may be configured to amplify the down-converted signals, and filter circuit 303 may be a low-pass filter (LPF) or band-pass filter (BPF) configured to remove unwanted signals from the down-converted signals to generate output baseband signals. Output baseband signals may be provided to another component, e.g., a modem, for further processing. The output baseband signals may be zero-frequency baseband signals, although this is not a requirement.

The mixer circuit 301 for a receive signal path may include passive mixers, although the scope of this disclosure is not limited in this respect. The mixer circuit 301 for a transmit signal path may be configured to up-convert input baseband signals based on the synthesized frequency provided by the synthesizer circuit 302 to generate radio frequency (RF) output signals. Amplifier circuit 305 may be configured to amplify the radio frequency (RF) output signals, and filter circuit 303 may be a low-pass filter (LPF) or band-pass filter (BPF) configured to remove unwanted signals from the up-converted signals to provide communication signals to be transmitted. The radio frequency (RF) communication signals may be provided to another component, to an antenna port or an antenna.

The mixer circuit 301 of the receive signal path and the mixer circuit 301 of the transmit signal path may include two or more mixers and may be arranged for quadrature down conversion and up conversion, respectively. The mixer circuit 301 of the receive signal path and the mixer circuit 301 of the transmit signal path may include two or more mixers and may be arranged for image rejection (e.g., Hartley image rejection). The mixer circuit 301 of the receive signal path and the mixer circuit 301 may be arranged for direct down conversion and direct up conversion, respectively. The mixer circuit 301 of the receive signal path and the mixer circuit 301 of the transmit signal path may be configured for super-heterodyne operation.

In some dual-mode aspects, a separate radio IC circuit may be provided for processing signals for each spectrum, although the scope of this disclosure is not limited in this respect.

The synthesizer circuit 302 may be a fractional-N synthesizer or a fractional N/N+1 synthesizer, although the scope of this disclosure is not limited in this respect as other types of frequency synthesizers may be suitable. For example, synthesizer circuit 302 may be a delta-sigma synthesizer, a frequency multiplier, or a synthesizer including a phase-locked loop with a frequency divider.

The synthesizer circuit 302 may be configured to synthesize an output frequency for use by the mixer circuit 301 of the radio communication circuit 300 based on a frequency input and a divider control input. The synthesizer circuit 302 may be a fractional N/N+1 synthesizer.

Frequency input may be provided by a voltage-controlled oscillator (VCO), although that is not a requirement. Divider control input may be provided by a processing component of the radio communication circuit 300 or may be provided by any suitable component, such as an external component like a modem. For example, the modem may provide a divider control input depending on the desired output frequency. A divider control input (e.g., N) may be determined from a look-up table based on a channel indicated by an external component.

Synthesizer circuit 302 of the radio communication circuit 300 may include a divider, a delay-locked loop (DLL), a multiplexer, and a phase accumulator. The divider may be a dual modulus divider (DMD) and the phase accumulator may be a digital phase accumulator (DPA). The DMD may be configured to divide the input signal by either N or N+1 (e.g., based on a carry out) to provide a fractional division ratio. The DLL may include a set of cascaded, tunable, delay elements, a phase detector, a charge pump, and a D-type flip-flop. The delay elements may be configured to break a VCO period up into No equal packets of phase, where Nd is the number of delay elements in the delay line. In this way, the DLL provides negative feedback to help ensure that the total delay through the delay line is one VCO cycle.

Synthesizer circuit 302 may be configured to generate a carrier frequency as the output frequency. The output frequency may be a multiple of the carrier frequency (e.g., twice the carrier frequency, four times the carrier frequency) and used in conjunction with quadrature generator and divider circuit to generate multiple signals at the carrier frequency with multiple different phases with respect to each other. The output frequency may be a LO frequency (fLO). The radio communication circuit 300 may include an IQ/polar converter.

While the radio communication circuit 300 described herein includes traditional super-heterodyning schemes or architectures, other types of transceiver or transmitter architectures and schemes may be used. The radio communication circuit 300 may include components to implement a near zero IF scheme, a Direct Conversion scheme, or a digital transmission scheme, such as, for example, a Digital IQ transmission, a Digital Polar transmission, and the like.

The radio communication circuit 300 may include a transmit path that includes or implements a direct digital transmitter (DDT). That is, a DDT may include a digital signal processor, an RF digital-to-analog converter (RFDAC), an RF filter/antenna coupler. Further, a DDT may be implemented with or without an IQ-mixer. In general, an RF-DAC may be included on an RFIC to convert digital input into an RF signal. A DDT may include other digital components such as numerically controlled oscillator (NCO) and digital mixers for shifting an input signal to the desired frequency.

The use of a DDT can reduce the number of analog components needed in the transmitter or transmit path. For example, analog LOs, analog filters, analog mixers, and etc., may be eliminated from the RFIC when a direct digital transmitter such as DDT is employed. Further, the use of a digital transmitter or digital transmission schemes may bring energy savings and efficiencies.

Further, the radio communication circuit 300 may include an impedance matching circuit 307 to provide impedance matching between other circuits, or in other words, provide matching with a load. The load may be other circuits or components that are configured to receive a signal from a circuit. The impedance matching circuit 307 may provide impedance matching between a circuit and a load.

FIG. 4 illustrates schematically a block diagram of an exemplary radio communication device 400 or system. The components of the radio communication device 400 are provided for ease of explanation, and in other cases, the radio communication device 400 can include additional, less, or alternative components as those shown in FIG. 4.

As shown in FIG. 4, the radio communication device 400 can include a radio communication circuit 401, exemplarily the radio communication circuit provided with respect to FIG. 3, a processing circuit 402, a memory 403. The radio communication device 400 may include miscellaneous components, modules, or portions 404 as well. The radio communication device 400 may include a modem or SoC. The radio communication device 400 may include one or more power sources, display interfaces, peripheral devices, ports (e.g., input, output), etc.

The radio communication device 400 may be used for products involving 5G, Wifi, BT, UWB, or any suitable wireless network products. The radio communication device 400 may also be used for any device supporting data-intensive applications, including streaming video (e.g., 4K, 8K video) or augmented/virtual reality (AR/VR) devices. The radio communication device 400 may also be used for vehicles, e.g., to help support a self-driving car and/or to be used as vehicle network. The radio communication device 400 may be used for Vehicle-to-everything (V2X) which includes vehicle-to-vehicle (V2V) and vehicle-to-infrastructure (V2I).

The processing circuit 402 may include any suitable number and/or type of computer processors, such as, for facilitating control of the radio communication device 400. In some cases, the processing circuit 402 may include a baseband processor (or suitable portions thereof) implemented by the radio communication device. In other cases, the processing circuit 402 may be one or more processors that are separate from the baseband processor (e.g., one or more digital signal processors). The processing circuit 402 may be working together with a processing circuit of the radio communication circuit 401. The processing circuit 402 may include a processing circuit of the radio communication circuit 401. Additionally, or alternatively, other examples may include various functions discussed herein by the processing circuit 402.

The processing circuit 402 may be configured to carry out instructions to perform arithmetical, logical, and/or input/output (I/O) operations, and/or to control the operation of one or more components of the radio communication device 400. For example, the processing circuit 402 can include one or more microprocessors, memory registers, buffers, clocks, etc. Moreover, aspects include processing circuit 402 communicating with and/or controlling functions associated with the memory 403 and/or functions of the radio.

The memory 403 may store data and/or instructions such that, when the instructions are executed by the processing circuit 402, the processing circuit 402 performs the various functions described herein. The memory 403 may be implemented as a non-transitory computer-readable medium storing one or more executable instructions such as, for example, logic, algorithms, code, etc. Instructions, logic, code, etc., stored in the memory 403 may enable the aspects disclosed herein to be functionally realized.

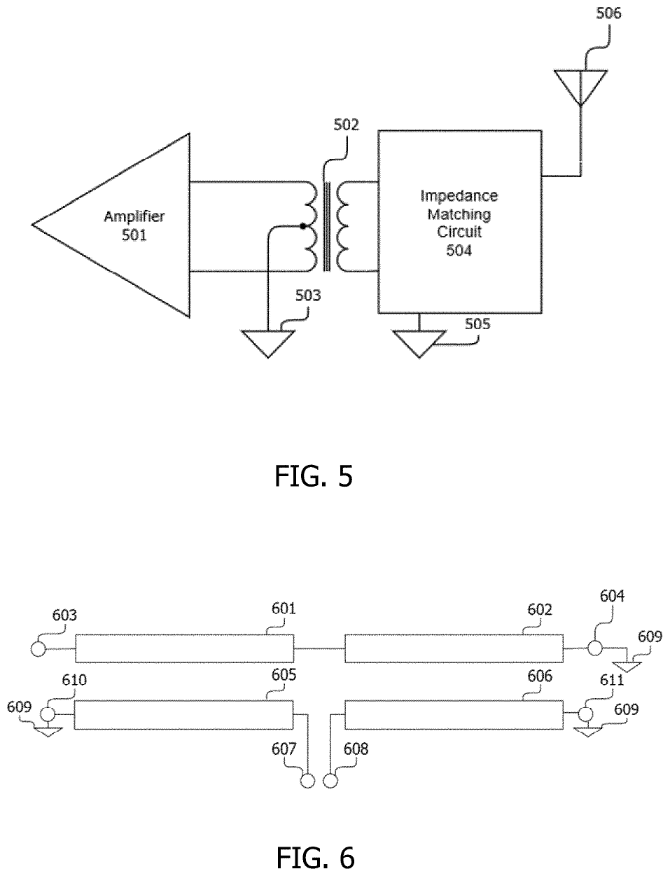

FIG. 5 shows schematically an example of an input of a low noise amplifier in a radio communication circuit. The low noise amplifier (LNA) 501 may be a differential amplifier configured to receive a differential RF signal. The radio communication circuit may be coupled to an antenna 506 to receive RF communication signals. Accordingly, a balun 502 including a transformer, and an impedance matching circuit 504 are provided between the antenna 506 and the LNA 501 to provide a conversion of an unbalanced RF signal provided by the antenna 506 to a balanced RF signal (differential RF signal) provided to the LNA 501, while the impedance matching circuit 504 matching impedance of the input of the LNA 501.

The RF communication signal received by the antenna 504 is provided to the impedance matching circuit 504. The impedance matching circuit 504 receives the signal from the antenna 506 and provides the signal to the balun 502 by matching the impedance of the signal path and a ground terminal 505. The RF signal provided by the impedance matching circuit 504 is still an unbalanced RF signal at this stage. The balun 502 converts the unbalanced signal to a balanced signal through coupling the RF signal magnetically between the windings of the transformer, which couples the unbalanced RF signal as a balanced RF signal due to provided ground terminal 503. Accordingly, the LNA 501 receives the balanced RF signal.

FIG. 6 shows schematically an example of a balun. The balun may be a coupled line balun. The balun is configured to provide conversion between an unbalanced signal and a balanced signal, and a balun, in general, works as a two sided component, hence it does not have an actual predefined input and/or output, although it will be described in this disclosure according to the context to provide simplicity. The balun includes an unbalanced structure 601, 602 including a first unbalanced component 601, and a second unbalanced component 602. The first unbalanced component 601 is coupled to a first input terminal 603 on one side, and the first unbalanced component 601 is coupled to one side of the second unbalanced component 602 on the other side. The other side of the second unbalanced component 602 is further coupled to a second input terminal 604.

Further, the balun includes a balanced structure 605, 606 including a first balanced component 605, and a second balanced component 606. The first balanced component 605 is coupled to a first output terminal 607 on one side, and the first balanced component 605 is coupled to a first further terminal 610 on the other side. Similarly, the second balanced component is 606 is coupled to a second output terminal 608 on one side, and the second balanced component 606 is coupled to a second further terminal 611 on the other side. The first balanced component 605 and the first unbalanced component 601 are configured to couple each other (either magnetically or electro-magnetically, based on the type of the balun). Similarly, the second balanced component 606 and the second unbalanced component 602 are configured to couple each other (either magnetically or electro-magnetically, based on the type of the balun).

Accordingly, when the balun is coupled to signal paths to convert an unbalanced signal to a balanced signal, the balun may receive the unbalanced signal from the first input terminal 603. The second input terminal 604 of the balun may be coupled to a ground 609. The received unbalanced signal flows through the first unbalanced component 601, the second unbalanced component 602, and the second input terminal 603 to the ground 609.

Furthermore, the first further terminal 610 and the second further terminal 611 may be coupled to the ground 609. While the unbalanced signal flows through the first unbalanced component 601, and the second unbalanced component 602, the coupling between the first unbalanced component 601 and the first balanced component 605 and the coupling between the second unbalanced component 602 and the second balanced component 606 provides a conversion of the unbalanced signal to a balanced signal comprising a first signal, and a second signal with a phase shift of 180 degrees related to the first signal from the first output terminal 607 and the second output terminal 608 respectively. Due to magnetic (or electro-magnetic) coupling, the impedance between the first output terminal 607 and the second output terminal 608 will be equal to impedances of the first balanced component 605 and the second balanced component 606.

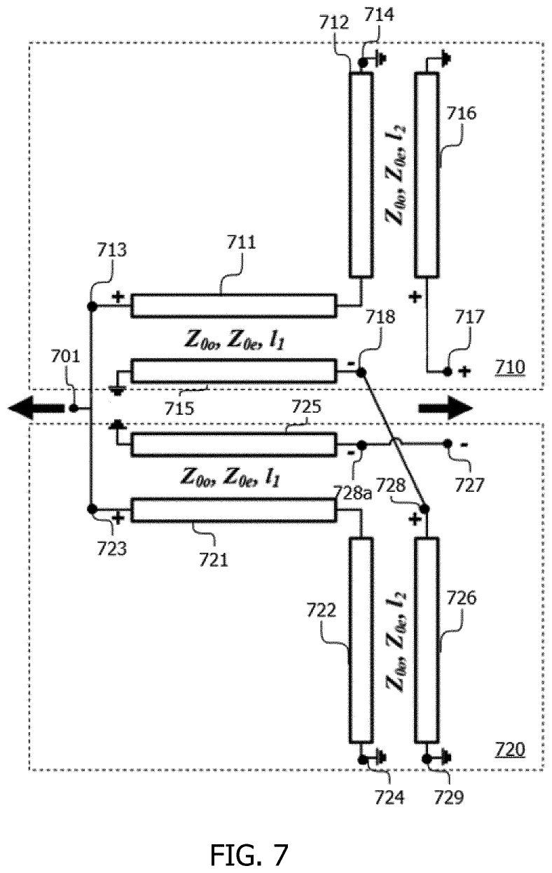

FIG. 7 shows schematically an example of an impedance matching circuit. The impedance matching circuit may include a first balun 710 including input terminals and output terminals and a second balun 720 including input terminals and output terminals, the input terminals of the first balun 710 and the second balun 720 may be coupled in parallel, and the output terminals of the first balun 710 and the second balun 720 may be coupled in series. Due to this coupling, a higher impedance ratio between one side of the impedance matching circuit (e.g. input terminals of the first balun 710 and the second balun 720) and the other side of the impedance matching circuit (e.g. output terminals of the first balun 710 and the second balun 720) may be provided.

In more detail, the impedance matching circuit may include a first impedance matching element 710. The first impedance matching element 710 may include a balun. The first impedance matching element 710 may include a first input including an unbalanced signal input terminal 713 and a ground terminal 714. The first impedance matching element 710 may include a first output. The first impedance matching element 710 may include an unbalanced structure 711, 712 including a first unbalanced component 711, and a second unbalanced component 712. The first unbalanced component 711 may be coupled to the input terminal 701 through the unbalanced signal input terminal 713 on one side, and the first unbalanced component 711 may be coupled to one side of the second unbalanced component 712 on the other side. The other side of the second unbalanced component 712 may be further coupled to the ground.

Further, the impedance matching circuit may include a second impedance matching element 720. The second impedance matching element 720 may include a balun.

The second impedance matching element 720 may include a second input including an unbalanced signal input terminal 723 and a ground terminal 724. The second impedance matching element 720 may include a second output. The second impedance matching element 720 may include an unbalanced structure 721, 722 including a first unbalanced component 721, and a second unbalanced component 722. The first unbalanced component 721 may be coupled to the input terminal 723 on one side, and the first unbalanced component 721 may be coupled to one side of the second unbalanced component 722 on the other side. The other side of the second unbalanced component 722 may be further coupled to ground.

Due to coupling of the unbalanced structure 711, 712 of the first impedance matching element 710, to the unbalanced structure 721, 722 of the second impedance matching element 720, the recognized impedance between the input terminal 701 of the impedance matching circuit and the respective ground terminal will be the combination of an input impedance of the first impedance matching element 710, and an input impedance of the second impedance matching element 720.

In other words, the first impedance matching element 710 may be configured to match a first input impedance of Z_{i,1} via the unbalanced structure 711, 712 between an unbalanced signal input terminal 713 and a ground terminal 714 coupled to the unbalanced structure 711, 712. The second impedance matching element 720 may be configured to match a second input impedance of Z_{i,2} via the unbalanced structure 721, 722 between an unbalanced signal input terminal 723 and a ground terminal 724 coupled to the unbalanced structure 722, 723. The first input impedance and the second input impedance are based on even mode/odd mode impedances of the components, and electrical lengths of the components of the first input matching element, and the second input matching element respectively, however, this will not be discussed herein.

The provided coupling at the input terminal 701 may accordingly be configured to match an input impedance based on the first input impedance and the second input impedance. For example, since the inputs of the first impedance matching element 710 and the second impedance matching element 720 are coupled in parallel, a recognized input impedance between the input terminal 701 and a ground terminal may be Zᵢ=Z_{i,1}*Z_{i,2}/(Z_{i,1}+Z_{i,2}).

The first impedance matching element 710 may further include a balanced structure 715, 716 including a first balanced component 715, and a second balanced component 716. The first balanced component 715 of the first matching element 710 may be coupled to the ground on one side. Further, the second impedance matching element 720 may include a balanced structure 725, 726 including a first balanced component 725, and a second balanced component 726. While the first balanced component 715 of the first matching element 710 may be coupled to the ground on the one side, the first balanced component 715 of the first matching element 710 may be coupled to the second balanced component 726 of the second matching element 720 on the other side. The second balanced component 726 of the second matching element 720 may be coupled to a ground terminal 729 on the other side.

The second balanced component 716 of the first impedance matching element 710 may be coupled to a ground terminal on one side, and the second balanced component 716 of the first impedance matching element 710 may be coupled to a first output terminal 717 to provide a first output signal. The first balanced component 725 of the second impedance matching element 720 may be coupled to a ground terminal on one side, and the first balanced component 725 of the second impedance matching element 720 may be coupled to a second output terminal 727 on the other side to provide a second output signal.

Due to provided coupling of the balanced structure 715, 716 of the first impedance matching element 710, to the balanced structure 725, 726 of the second impedance matching element 720, the recognized impedance between the first output terminal 717 and the second output terminal 727 of the impedance matching circuit will be the combination of an output impedance of the first impedance matching element 710 and an output impedance of the second impedance matching element 720.

In other words, the first impedance matching element 710 may be configured to match a first output impedance of Z_{o,1} via the balanced structure 715, 716. The second impedance matching element 720 may be configured to match a second output impedance of Z_{o,2} via the balanced structure 725, 726. The first output impedance and the second output impedance are based on even mode/odd mode impedances of the components, and electrical lengths of the components of the first input matching element 710, and the second input matching element 720 respectively, however, this will not be discussed herein.

The provided coupling of the first balanced component 715 of the first impedance matching element 710 and the second balanced component 726 of the second impedance matching element 720 from one of the respective output terminals 718 and 728 of the first impedance matching element 710 and the second matching element 720 may cause the impedance matching circuit to match an output impedance based on the first output impedance and the second output impedance between the first output terminal 717 and the second output terminal 727. For example, since the outputs of the first impedance matching element 710 and the second impedance matching element 720 are coupled in series, the output impedance of the impedance matching circuit between the first output terminal 717 and the second output terminal 727 may be Zₒ=Z_{o,1}+Z_{o,2}.

Accordingly, the impedance matching circuit may be configured to receive an unbalanced input signal from the input terminal 701. The first impedance matching element 710, and the second impedance matching element 720 may be coupled at their inputs, e.g. an unbalanced port, to receive a signal from a signal path. The first impedance matching element 710 may receive the unbalanced signal and couple the unbalanced signal via the unbalanced structure 711, 712 of the first impedance matching element 710 to the balanced structure 715, 716 of the first impedance matching element 710. Similarly, the second impedance matching element 720 may receive the unbalanced signal and couple the unbalanced signal via the unbalanced structure 721, 722 of the second impedance matching element 720 to the balanced structure 725, 726 of the second impedance matching element 720.

As explained above, one output 718 of the first balanced structure 715 of the first impedance matching element 710, and one output 728 of the second balanced structure 726 of the second impedance matching element 720 are coupled, and accordingly, the output signal may be provided from the first output terminal 717 as a first signal including a first balanced signal, and from the second output terminal 727 as a second signal including a second balanced signal. And as explained above, due to provided coupling of the balanced structure 715, 716 of the first impedance matching element 710, to the balanced structure 725, 726 of the second impedance matching element 720, the recognized impedance between the first output terminal 717 and the second output terminal 727 of the impedance matching circuit will be the combination of the output impedance of the first impedance matching element 710 and an output impedance of the second impedance matching element 720.

Accordingly, the first output terminal 717 may provide the first output signal that may include a first balanced signal. Similarly, the second output terminal 727 may provide the second output signal that may include a second balanced signal. The first balanced signal and the second balanced signal collectively may include the unbalanced signal that is converted to a balanced signal.

The components of the matching elements may include conductors. The components may include transmission lines (e.g. coupled lines). The impedance matching elements may further include capacitors to provide a further capacitive matching. The coupling between unbalanced structures and balanced structures may include electro-magnetic coupling.

The first matching element 710 may have 1:1 impedance matching ratio. Accordingly, the input impedance of the first matching element 710 and the output impedance of the first matching element 710 may be configured to match the same impedance. Similarly, the second matching element 720 may also have 1:1 impedance matching ratio. Accordingly, the input impedance of the second matching element 720 and the output impedance of the second matching element 720 may be configured to match the same impedance. Accordingly, the impedance matching circuit may be configured to provide an impedance matching with an impedance matching ratio 1:4 by employing a first impedance matching element with 1:1 impedance matching ratio and a second impedance matching element with 1:1 impedance matching ratio that are having substantially the same characteristics. In other words, the output impedance of the impedance matching circuit may be four times the input impedance of the impedance matching circuit. Such arrangement may further provide a symmetric coupling with the first impedance element and the second impedance element, and it may provide desired capacitance characteristics.

Furthermore, since the first impedance matching element 710 is configured to convert the unbalanced signal to the balanced signal through the coupling provided between the unbalanced structure 711, 712 and the balanced structure 715, 716, the line lengths of the coupled-lines may be configured to be different to change the coupling area between the coupled-lines to decrease provided phase and amplitude imbalance. In this example, the first unbalanced component 711 of the first impedance matching element 710 is configured to couple the unbalanced signal to the first balanced component 715 of the first impedance matching element 710 electro-magnetically over the first line length (and width) of the first unbalanced component 711 and the first balanced component 715. Similarly, the second unbalanced component 712 is configured to couple the unbalanced signal to the second balanced component 716 electro-magnetically over the second line length (and width) of the second unbalanced component 712, and the second balanced component 716.

Accordingly, each of the first unbalanced component 711 and the first balanced component 715 may include a conductor having a first predefined line length, or in other words, the first unbalanced component 711 and the first balanced component 715 may be configured to couple each other over a first predefined line length. Additionally, each of the second unbalanced component 712 and the second balanced component 716 may include a conductor a second predefined line length, or in other words, the second unbalanced component 712 and the second balanced component 716 may be configured to couple each other over a second predefined line length. The first predefined line length may be shorter or longer than the second predefined line length to reduce the amplitude and/or phase imbalance.

Similarly, since the second impedance matching element 720 is configured to convert the unbalanced signal to the balanced signal through the coupling provided between the unbalanced structure 721, 722 and the balanced structure 725, 726, the line lengths of the coupling pairs may be configured to have different lengths to change the coupling area between the coupling pairs to decrease provided phase and amplitude imbalance. In this example, the first unbalanced component 721 of the second impedance matching element 720 is configured to couple the unbalanced signal to the first balanced component 725 of the second impedance matching element 720 electro-magnetically over the first line length (and width) of the first unbalanced component 721 and the first balanced component 725. Similarly, the second unbalanced component 722 is configured to couple the unbalanced signal to the second balanced component 726 electro-magnetically over the second line length (and width) of the second unbalanced component 722, and the second balanced component 726.

Accordingly, each of the first unbalanced component 721 and the first balanced component 725 may include a conductor having a first predefined line length, or in other words, the first unbalanced component 721 and the first balanced component 725 may be configured to couple each other over a first predefined line length. Additionally, each of the second unbalanced component 722 and the second balanced component 726 may include a conductor a second predefined line length, or in other words, the second unbalanced component 722 and the second balanced component 726 may be configured to couple each other over a second predefined line length. The first predefined line length may be shorter or longer than the second predefined line length to reduce the amplitude and/or phase imbalance.

It may be desirable to make the first line length for the first unbalanced component 711 and the first balanced component 715 of the first impedance element 710 and the first line length for the first unbalanced component 721 and the first balanced component 725 of the second impedance element 720 substantially equal. It may also be desirable to make the second line length for the second unbalanced component 712 and the second balanced component 716 of the first impedance element 710 and the second line length for the second unbalanced component 722 and the second balanced component 726 of the second impedance element 720 substantially equal. The first line length may be longer or shorter than the second line length. It may further be desirable to keep the total line length for the balanced structure and the unbalanced structure constant which may provide good impedance matching and loss characteristics for the impedance matching circuit.

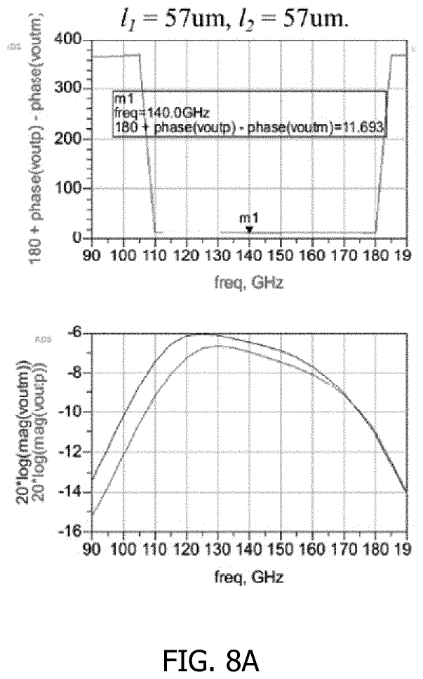

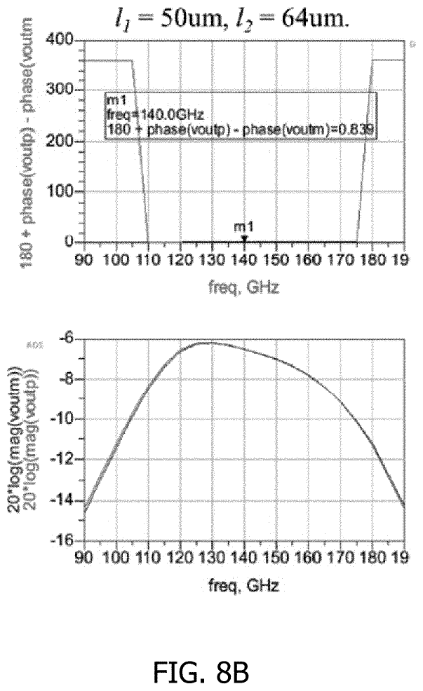

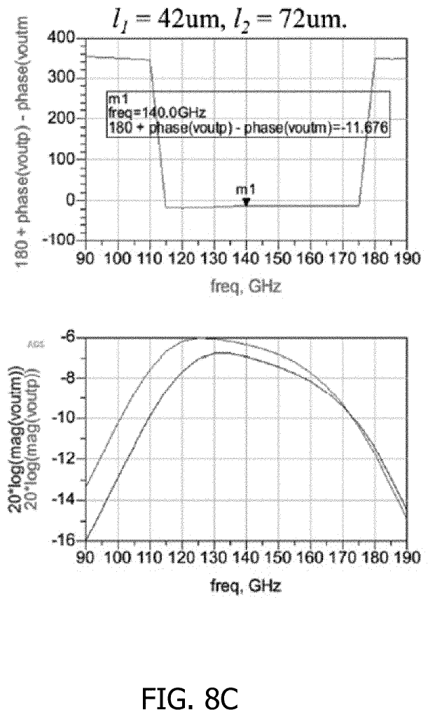

FIG. 8A shows schematically a diagram for a coupled-line balun having coupled lines with the same line lengths. The coupled-line balun is designed as the input match for a low-noise amplifier configured to operate with a signal at 140 GHz. The diagram below shows an amplitude imbalance of around 1 dB, and the diagram above shows a phase imbalance around 11.5 degrees for output signals, for a case where the line lengths are 57 μm.

FIG. 8B shows schematically a diagram for a coupled-line balun having coupled lines with different line lengths. The coupled-line balun is designed as the input match for a low-noise amplifier configured to operate with a signal at 140 GHz. The diagram below shows an amplitude imbalance of less than 0.1 dB, and the diagram above shows a phase imbalance of less than 1 degree for output signals, for a case where the first line length is 50 μm and the second line length is 64 μm.

FIG. 8C shows schematically a diagram for a coupled-line balun having coupled lines with different line lengths. The coupled-line balun is designed as the input match for a low-noise amplifier configured to operate with a signal at 140 GHz. The diagram below shows an amplitude imbalance around −1 dB, and the diagram above shows a phase imbalance around −11 degrees for output signals, for a case where the first line length is 42 μm and the second line length is 72 μm.

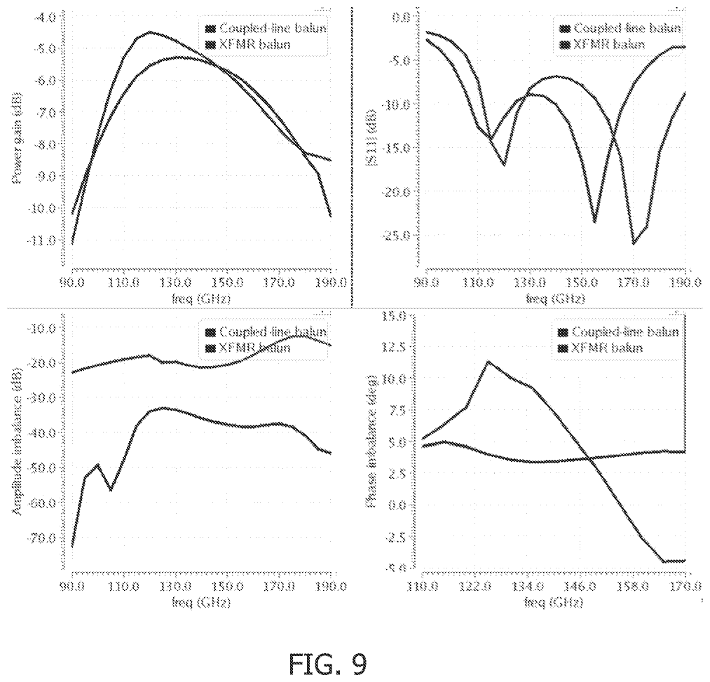

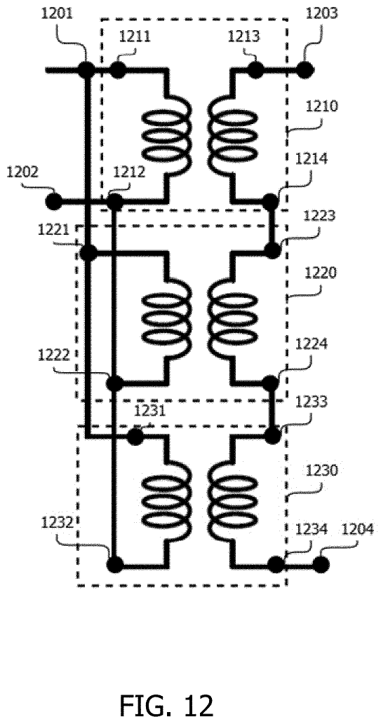

FIG. 9 shows schematically a diagram for certain characteristics of a coupled-line balun provided in FIG. 7, and a 1:4 transformer based balun provided in FIG. 12. Both impedance matching circuits are designed as the input match for a low-noise amplifier configured to operate with a signal at 140 GHz. The shown characteristics include power gain in dB, reflection coefficient S11, amplitude imbalance, and phase imbalance. The diagram shows a wideband input match lower than −9 dB from 105 GHz. to 170 GHz, a loss of 5.5 dB, and 3 dB from 100 GHz. to 180 GHz. An amplitude imbalance lower than −30 dB and a phase imbalance lower than 5 degrees across the band of operation.

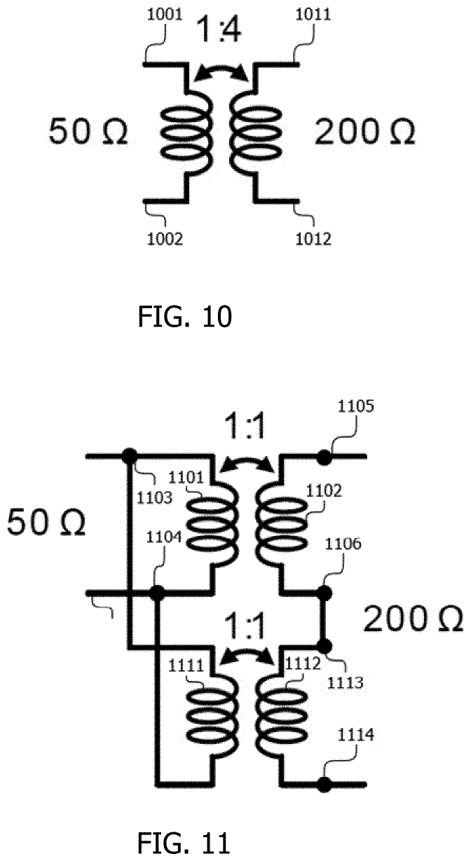

FIG. 10 shows schematically an example of an impedance matching circuit including a transformer. The transformer includes a primary winding and a secondary winding. The primary winding may be coupled to a first input terminal 1001, and a second input terminal 1002. The secondary winding may be coupled to a first output terminal 1011 and a second output terminal 1012. As previously discussed for baluns above, the input of the transformer depends on the context. The transformer is configured to match an input impedance of 50 ohms between the first input terminal 1001 and the second input terminal 1002. The transformer is configured to match an output impedance of 200 ohms between the first output terminal 1011 and the second output terminal 1012. In order to provide the matching ratio of 1:4, the transformer may need a ratio of the inductance of the primary winding to secondary winding at 1:16.

FIG. 11 shows schematically an example of an impedance matching circuit. The impedance matching circuit may include a first impedance matching element including a first transformer balun, and a second impedance matching element including a second transformer balun. The first transformer balun may include a primary winding 1101 and a secondary winding 1102. The primary winding 1101 of the first transformer balun may be coupled to a first input terminal 1103 on one side and to a second input terminal 1104 on the other side. The second transformer balun may include a primary winding 1111 and a secondary winding 1112. The primary winding 1111 of the second transformer balun may be coupled to the first input terminal 1103 on one side and to the second input terminal 1104 on the other side.

As similarly discussed herein especially with respect to FIG. 7, due to coupling of the primary winding 1101 of the first transformer balun and primary winding 1111 of the second transformer balun, a recognized impedance between the first input terminal 1103 and the second input terminal 1104 will be a combination of an input impedance of the first transformer balun and an input impedance of the second transformer balun.

In other words, the primary winding 1101 of the first transformer balun may be configured to match a first input impedance of Z_{i,1}, between its respective input terminals 1103, 1104, and the primary winding 1111 of the second transformer balun may be configured to match a second input impedance of Z_{i,2} between its respective terminals 1103, 1104. The provided coupling at the first input terminal 1103 and the second input terminal 1104 may be configured to match an input impedance based on the first input impedance and the second input impedance. For example, since the inputs of the primary winding 1101 of the first transformer balun and the inputs of the primary winding 1111 of the second transformer balun are coupled in a parallel configuration, a recognized input impedance between the first input terminal 1103 and the second input terminal 1104 may be Zᵢ=Z_{i,1}*Z_{i,2}/(Z_{i,1}+Z_{i,2}).

Furthermore, the secondary winding 1102 of the first transformer balun may be coupled to a first output of the first transformer balun. The first output may include a first output terminal 1105 and a second output terminal 1106. The secondary winding 1112 of the second transformer balun may be coupled to a second output of the second transformer balun. The second output may include a first output terminal 1113 and a second output terminal 1114. The first output and the second output may be coupled in a series configuration. In other words, the second output terminal 1106 of the first transformer balun may be coupled to a first output terminal 1113 of the second transformer balun.

Due to provided electrical coupling of the first output and the second output, the recognized impedance between the first output terminal 1105 of the first transformer balun and the second output terminal 1114 of the second transformer balun will be the combination of an output impedance of the first transformer balun and an output impedance of the second transformer balun.

In other words, the first transformer balun may be configured to match a first output impedance of Z_{o,1} the secondary winding 1102 of the first transformer balun. The second transformer balun may be configured to match a second output impedance of 42 via the secondary winding 1112 of the second transformer balun. The provided coupling of the secondary winding 1102 of the first transformer balun and the secondary winding 1112 of the second transformer balun may cause the impedance matching circuit to match an output impedance based on the first output impedance and the second output impedance between the first output terminal 1105 of the first transformer balun and the second output terminal 1114 of the second transformer balun. For example, since the outputs of the first transformer balun and the second transformer balun are coupled in series, the output impedance of the impedance matching circuit between the first output terminal 1105 of the first transformer balun and the second output terminal 1114 of the second transformer balun may be Zₒ=Z_{o,1}+Z_{o,2}.

Accordingly, the impedance matching circuit may be configured to receive an unbalanced input signal from one of the input terminals 1103, 1104. The first transformer balun and the second transformer balun may be coupled at their inputs. The first transformer balun may receive the unbalanced signal and couple the unbalanced signal via the primary winding 1101 to the secondary winding 1102 of the first transformer balun. Similarly, the second transformer balun may receive the unbalanced signal and couple the unbalanced signal via the primary winding 1111 to the secondary winding 1112 of the second transformer balun.

As explained above, the second output terminal 1106 of the first transformer balun is coupled to the first output terminal 1113 of the second transformer balun, and accordingly, the output signal may be provided from the first output terminal 1105 of the first transformer balun as a first signal including a first balanced signal, and from the second output terminal 1114 of the second transformer balun as a second signal including a second balanced signal. And as explained above, due to provided coupling of the secondary winding 1102 of the first transformer balun and the secondary winding 1112 of the second transformer balun, the recognized impedance between the first output terminal 1105 of the first transformer balun and the second output terminal 1114 of the second transformer balun will be the combination of the output impedance of the first transformer balun and an output impedance of the transformer balun.

Accordingly, the first output terminal 1105 of the first transformer balun may provide the first output signal that may include a first balanced signal to a first output of the impedance matching circuit. Similarly, the second output terminal 1114 of the second transformer balun may provide the second output signal that may include a second balanced signal to a second output of the impedance matching circuit. The first balanced signal and the second balanced signal collectively may include the unbalanced signal that is converted to a balanced signal.

The first transformer balun may have 1:1 impedance matching ratio. Accordingly, the input impedance of the first transformer balun and the output impedance of the first transformer balun may be configured to match the same impedance. Similarly, the second transformer balun may also have 1:1 impedance matching ratio. Accordingly, the input impedance of the second transformer balun and the output impedance of the second transformer balun may be configured to match the same impedance. Accordingly, the impedance matching circuit may be configured to provide an impedance matching with an impedance matching ratio 1:4 by employing a first transformer balun with 1:1 impedance matching ratio and a second transformer balun with 1:1 impedance matching ratio that are having substantially the same characteristics. In other words, the output impedance of the impedance matching circuit may be four times the input impedance of the impedance matching circuit. Such arrangement may further provide a symmetric coupling with the first impedance element and the second impedance element, and it may provide desired capacitance characteristics.

FIG. 12 shows schematically an example of an impedance matching circuit. The impedance matching circuit may include a first input terminal 1201, a second input terminal 1202, a first output terminal 1203, a second output terminal 1204, and a plurality of impedance matching elements including a first impedance matching element 1210, a second impedance matching element 1220, and a third impedance matching element 1230. Aspects discussed in this disclosure with respect to impedance matching elements may also apply to the impedance matching elements discussed herein.

The first impedance matching element 1210 includes an input including a first input terminal 1211, a second input terminal 1212, and an output including a first output terminal 1213 and a second output terminal 1214. The first impedance matching element 1210 is configured to receive an input signal from the input and magnetically couple the input signal to the output. The output of the first impedance matching element 1210 is configured to match a first output impedance. The input of the first impedance matching element 1210 is configured to match a first input impedance.

The second impedance matching element 1220 includes an input including a first input terminal 1221, a second input terminal 1222, and an output including a first output terminal 1223 and a second output terminal 1224. The second impedance matching element 1220 is configured to receive an input signal from the input and magnetically couple the input signal to the output. The output of the second impedance matching element 1220 is configured to match a second output impedance. The input of the second impedance matching element 1220 is configured to match a second input impedance.

The third impedance matching element 1230 includes an input including a first input terminal 1231, a second input terminal 1232, and an output including a first output terminal 1233 and a second output terminal 1234. The third impedance matching element 1230 is configured to receive an input signal from the input and magnetically couple the input signal to the output. The output of the third impedance matching element 1230 is configured to match a third output impedance. The input of the third impedance matching element 1230 is configured to match a third input impedance.

The inputs of each of the first impedance matching element 1210, the second impedance matching element 1220, and the third impedance matching element 1230 are coupled to the first input terminal 1201 and the second input terminal 1202 of the impedance matching circuit in a parallel configuration. Accordingly, Z_{i,1} being the first input impedance, Z_{i,2} being the second input impedance, and Z_{i,3} being the third input impedance, the impedance matching circuit is configured to match the input impedance of Zᵢ=Z_{i,1}*Z_{i,2}*Z_{i,3}/(Z_{i,1}+Z_{i,2}+Z_{i,3}).

The outputs of each of the first impedance matching element 1210, the second impedance matching element 1220, and the third impedance matching element 1230 are coupled in a series configuration. In more detail, the second output terminal 1214 of the first impedance matching element 1210 is coupled to the first output terminal 1223 of the second impedance matching element 1220. The second output terminal 1224 of the second impedance matching element 1220 is coupled to the first output terminal 1233 of the third impedance matching element 1230.

The first output terminal 1213 of the first impedance matching element 1210 is coupled to the first output terminal 1203 of the impedance matching circuit. Alternatively, the impedance matching circuit may be configured to provide the first output signal from the first output terminal 1213 of the first impedance matching element 1210. The second output terminal 1234 of the third impedance matching element 1230 is coupled to the second output terminal 1204 of the impedance matching circuit. Alternatively, the impedance matching circuit may be configured to provide the second output signal from the second output terminal 1234 of the third impedance matching element 1230.

Accordingly, Z_{o,1} being the first output impedance, Z_{o,2} being the second output impedance, and Z_{o,3} being the third output impedance, the impedance matching circuit is configured to match the output impedance of Zₒ=Z_{o,1}+Z_{o,2}+Z_{o,3}. Based on the coupling provided in this disclosure, namely electrical coupling of the impedance matching elements in a parallel configuration on one side (input), and in a series configuration on the other side, various matching impedance ratios may be obtained. For example, in case of each of the first impedance matching element 1210, the second impedance matching element 1220, and the third impedance matching element 1230 are configured to provide impedance matching with an impedance matching ratio of 1:1, the impedance matching circuit may be configured to provide an impedance matching ratio of 1:9. With the provided coupling of this constellation, an impedance matching circuit including N number of impedance matching elements may provide an impedance matching ratio of 1:N².

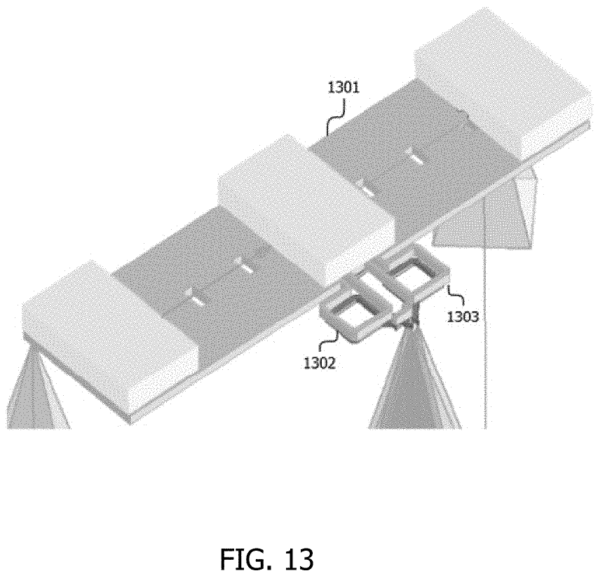

FIG. 13 shows schematically an example of an impedance matching circuit as provided in FIG. 11. The impedance matching circuit includes an input port 1301, a first impedance matching element 1302 including a first transformer balun, and a second impedance matching element 1303 including a second transformer balun. Input terminals of the first impedance matching element 1302 and the second impedance matching element 1303 are coupled in a parallel configuration to the input port 1301. Output terminals are coupled in a series configuration as schematized in FIG. 11. The characteristics of the impedance matching circuit are provided in the diagram of FIG. 9. The primary windings of the first impedance matching element 1302 and the second impedance matching element 1303 are laid out symmetrically to match the symmetric interface of probe pads provided as ground-signal-ground (GSG). The windings of the first impedance matching element 1302 and the second impedance matching element 1303 are further configured with a capacitance to cancel out the capacitance introduced by the ground-signal-ground (GSG) probe pads and the input of the low-noise amplifier which the impedance matching circuit is coupled to.

The following examples pertain to further aspects of this disclosure.

Example 1 includes an impedance matching circuit as a subject matter. The subject matter may include a first impedance matching element configured to: receive an unbalanced input signal from a first input, and couple the unbalanced input signal to a first output to match an impedance of the first output to a first impedance; a second impedance matching element coupled to the first input to receive the unbalanced input signal, the second impedance matching element configured to couple the unbalanced input signal to a second output to match an impedance of the second output to a second impedance; wherein a terminal of the first output and a terminal of the second output are coupled to provide a balanced output signal, and may include that the coupling matches an output impedance of the subject matter based on the first impedance and the second impedance.

In example 2, the subject matter of example 1, can optionally include that the first output includes a first output terminal and a second output terminal, and the second output includes a first output terminal and a second output terminal, and can optionally include that the second output terminal of the first output is coupled to the first output terminal of the second output, and can optionally include that the subject matter is configured to provide the balanced output signal from the first output terminal of the first output and the second output terminal of the second output.

In example 3, the subject matter of any one of examples 1 or 2, can optionally include that the first impedance matching element further includes a first input and the second impedance matching element further includes a second input; and can optionally include that the first input and the second input are coupled in a parallel configuration, and the first input is configured to match an impedance of the first input; and can optionally include that the second input is configured to match an impedance of the second input.

In example 4, the subject matter of any one of examples 1 to 3, can optionally include that the impedance of the first input substantially equals the first impedance, and the impedance of the second input substantially equals the impedance of the second impedance.

In example 5, the subject matter of any one of examples 1 to 4, can optionally include that the first impedance substantially equals the second impedance, and the output impedance of the subject matter is four times the first impedance.

In example 6, the subject matter of any one of examples 1 to 5, can optionally include that the first impedance matching element includes a first balun may include an unbalanced structure and a balanced structure, the first input being coupled to the unbalanced structure and the first output is coupled to the balanced structure; and can optionally include that the second impedance matching element includes a second balun may include an unbalanced structure and a balanced structure, can optionally include that the second input is coupled to the unbalanced structure and the second output is coupled to the balanced structure.

In example 7, the subject matter of example 6, can optionally include that the balanced structure of the first balun is configured to electro-magnetically couple the unbalanced structure of the first balun at a first predefined length of the balanced structure of the first balun; and can optionally include that the balanced structure of the second balun is configured to electro-magnetically couple the unbalanced structure of the second balun at a second predefined length of the balanced structure of the second balun.

In example 8, the subject matter of any one of examples 6 or 7, can optionally include that the unbalanced structure of the first balun includes a first unbalanced component with a first predefined length and a second unbalanced component with a second predefined length; and can optionally include that the balanced structure of the first balun includes a first balanced component with the first predefined length and a second balanced component with the second predefined length; and can optionally include that the first predefined length is different than the second predefined length.

In example 9, the subject matter of any one of examples 6 to 8, can optionally include that the first predefined length of the balanced structure of the first balun is equal to the second predefined length of the balanced structure of the second balun.

In example 10, the subject matter of any one of examples 6 to 9, can optionally include that the unbalanced structure of the second balun includes a first unbalanced component with a first predefined length and a second unbalanced component with a second predefined length; and can optionally include that the balanced structure of the second balun includes a first balanced component with the first predefined length and a second balanced component with the second predefined length; and can optionally include that the first predefined length is different than the second predefined length.

In example 11, the subject matter of any one of examples 6 to 10, can optionally include that the first output terminal and the second output terminal of the first output include a differential output of the balanced structure of the first balun; and can optionally include that the first output terminal and the second output terminal of the second output include a differential output of the balanced structure of the second balun.

In example 12, the subject matter of any one of examples 6 to 11, can optionally include that the first unbalanced component of the unbalanced structure of the first balun is coupled to the first input, and the second unbalanced component of the unbalanced structure of the first balun is coupled to the ground; and can optionally include that the first unbalanced component of the unbalanced structure of the second balun is coupled to the second input, and the second unbalanced component of the unbalanced structure of the second balun is coupled to the ground.

In example 13, the subject matter of any one of examples 1 to 3, can optionally include that the first impedance matching element includes a first transformer balun may include a primary winding and a secondary winding; and can optionally include that the second impedance matching element includes a second transformer balun may include a primary winding and a secondary winding.

In example 14, the subject matter of example 13, can optionally include that the first input includes a first input terminal and a second input terminal; and can optionally include that the first input terminal and the second input terminal of the first input are coupled to the primary winding of the first transformer balun; and can optionally include that the second input includes a first input terminal and a second input terminal; and can optionally include that the first input terminal and the second input terminal of the second input are coupled to the primary winding of the second transformer balun; and can optionally include that the secondary winding of the first transformer balun is coupled to the first output terminal and the second output terminal of the first output; and can optionally include that the secondary winding of the second transformer balun is coupled to the first output terminal and the second output terminal of the second output.

In example 15, the subject matter of any one of examples 13 or 14, further may include: a third impedance matching element may include a third transformer balun may include a primary winding and a secondary winding; and can optionally include that the primary winding of the third transformer balun is coupled to the first input in a parallel configuration; and can optionally include that the secondary winding of the third transformer is coupled to the first output and the second output in a series configuration.

In example 16, the subject matter of any one of examples 13 to 15, further may include an subject matter input coupled to a first signal path at which the primary winding of the first transformer balun, the primary winding of the second transformer balun, and the primary winding of the third transformer balun are coupled in parallel, an subject matter output may include two terminals coupled at a second signal path at which the secondary winding of the first transformer balun, the secondary winding of the second transformer balun, and the secondary winding of the third transformer balun are connected in series; and can optionally include that the output impedance of the subject matter is nine times the impedance of the subject matter input.

In example 17, the subject matter of any one of examples 13 to 16, further may include a plurality of impedance matching elements, can optionally include that each of the plurality of impedance matching elements may include a transformer balun may include a primary winding and a secondary winding; and can optionally include that the primary winding of each of the plurality of impedance matching elements are coupled to the first input in parallel, and the secondary winding of each of the plurality of impedance matching elements are coupled to the first output and the second output in series.

Example 18 includes an impedance matching element may include: a first conductor configured to receive an unbalanced input signal, and couple the unbalanced input signal electro-magnetically to a second conductor over a first predefined length of the second conductor; a third conductor electrically coupled to the first conductor, the third conductor configured to couple the unbalanced input signal electro-magnetically to a fourth conductor over a second predefined length of the fourth conductor, can optionally include that the second predefined length is different from the first predefined length.

Example 19 includes an impedance matching circuit as the subject matter. The subject matter may include: a first transformer may include a first primary winding and a first secondary winding, can optionally include that the first primary winding has a first primary impedance, and the first secondary winding has a second primary impedance; a second transformer may include a second primary winding and a second secondary winding, can optionally include that the second primary winding has a first primary impedance, and the second secondary winding has a second secondary impedance; and can optionally include that the second primary winding is coupled to the first primary winding in parallel, and the coupling of the first primary winding and the second primary winding matches an input impedance of the subject matter; and can optionally include that the second secondary winding and the second primary winding are coupled in series, can optionally include that the coupling of the first secondary winding and the second secondary winding matches an output impedance of the subject matter.

In example 20, the subject matter of example 19, can optionally include that the subject matter includes a number N of a plurality of transformers may include the first transformer and the second transformer; and can optionally include that the output impedance of the subject matter has an impedance substantially N2 times the input impedance of the subject matter.

The word “exemplary” is used herein to mean “serving as an example, instance, or illustration”. Any aspect or design described herein as “exemplary” is not necessarily to be construed as preferred or advantageous over other aspects or designs.

Throughout the drawings, it should be noted that like reference numbers are used to depict the same or similar elements, features, and structures, unless otherwise noted. It should be noted that certain components may be omitted for the sake of simplicity. It should be noted that nodes (dots) are provided to identify the circuit line intersections in the drawings including electronic circuit diagrams.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

As used herein, a signal that is “indicative of” or “indicating” a value or other information may be a digital or analog signal that encodes or otherwise, communicates the value or other information in a manner that can be decoded by and/or cause a responsive action in a component receiving the signal. The signal may be stored or buffered in computer-readable storage medium prior to its receipt by the receiving component and the receiving component may retrieve the signal from the storage medium. Further, a “value” that is “indicative of” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The terms “one or more processors” is intended to refer to a processor or a controller. The one or more processors may include one processor or a plurality of processors. The terms are simply used as an alternative to the “processor” or “controller”.

As utilized herein, terms “module”, “component,” “system,” “circuit,” “element,” “slice,” “circuit,” and the like are intended to refer to a set of one or more electronic components, a computer-related entity, hardware, software (e.g., in execution), and/or firmware. For example, circuit or a similar term can be a processor, a process running on a processor, a controller, an object, an executable program, a storage device, and/or a computer with a processing device. By way of illustration, an application running on a server and the server can also be circuit. One or more circuits can reside within the same circuit, and circuit can be localized on one computer and/or distributed between two or more computers. A set of elements or a set of other circuits can be described herein, in which the term “set” can be interpreted as “one or more.”

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D Points, among others, or any combination thereof. Registers, shift registers, processor registers, data buffers, among others, are also embraced herein by the term memory. The term “software” refers to any type of executable instruction, including firmware.

The term “antenna”, as used herein, may include any suitable configuration, structure and/or arrangement of one or more antenna elements, components, units, assemblies and/or arrays. The antenna may implement transmit and receive functionalities using separate transmit and receive antenna elements. The antenna may implement transmit and receive functionalities using common and/or integrated transmit/receive elements. The antenna may include, for example, a phased array antenna, a single element antenna, a set of switched beam antennas, and/or the like.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “provided” to an element, the voltage, current, or signal may be conducted to the element by way of a physical connection or by way of capacitive, electro-magnetic, or inductive coupling that does not involve a physical connection.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

Some aspects may be used in conjunction with one or more types of wireless communication signals and/or systems, for example, Radio Frequency (RF), Infra-Red (IR), Frequency-Division Multiplexing (FDM), Orthogonal FDM (OFDM), Orthogonal Frequency-Division Multiple Access (OFDMA), Spatial Divisional Multiple Access (SDMA), Time-Division Multiplexing (TDM), Time-Division Multiple Access (TDMA), Multi-User MIMO (MU-MIMO), General Packet Radio Service (GPRS), extended GPRS (EGPRS), Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth (BT), Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other aspects may be used in various other devices, systems and/or networks.

Some demonstrative aspects may be used in conjunction with a WLAN, e.g., a WiFi network. Other aspects may be used in conjunction with any other suitable wireless communication network, for example, a wireless area network, a “piconet”, a WPAN, a WVAN, and the like.

Some aspects may be used in conjunction with a wireless communication network communicating over a frequency band of 2.4 GHz, 5 GHz, and/or 6-7 GHz. However, other aspects may be implemented utilizing any other suitable wireless communication frequency bands, for example, an Extremely High Frequency (EHF) band (the millimeter wave (mmWave) frequency band), e.g., a frequency band within the frequency band of between 20 GHz and 300 GHz, a WLAN frequency band, a WPAN frequency band, and the like.

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An impedance matching circuit comprising:
a first impedance matching element configured to:
receive an unbalanced input signal from a first input, and
couple the unbalanced input signal to a first output to match an impedance of the first output to a first impedance;
a second impedance matching element coupled to the first input to receive the unbalanced input signal, the second impedance matching element configured to couple the unbalanced input signal to a second output to match an impedance of the second output to a second impedance;
wherein a terminal of the first output and a terminal of the second output are coupled to provide a balanced output signal, and wherein the coupling matches an output impedance of the impedance matching circuit based on the first impedance and the second impedance.

2. The impedance matching circuit of claim 1,
wherein the first output comprises a first output terminal and a second output terminal, and the second output comprises a first output terminal and a second output terminal, and
wherein the second output terminal of the first output is coupled to the first output terminal of the second output, and
wherein the impedance matching circuit is configured to provide the balanced output signal from the first output terminal of the first output and the second output terminal of the second output.

3. The impedance matching circuit of claim 2,
wherein the first impedance matching element further comprises a first input and the second impedance matching element further comprises a second input; and
wherein the first input and the second input are coupled in a parallel configuration, and the first input is configured to match an impedance of the first input; and
wherein the second input is configured to match an impedance of the second input.

4. The impedance matching circuit of claim 3,
wherein the impedance of the first input substantially equals the first impedance, and the impedance of the second input substantially equals the impedance of the second impedance.

5. The impedance matching circuit of claim 3,
wherein the first impedance substantially equals the second impedance, and the output impedance of the impedance matching circuit is four times the first impedance.

6. The impedance matching circuit of claim 3,
wherein the first impedance matching element comprises a first balun comprising an unbalanced structure and a balanced structure, the first input being coupled to the unbalanced structure and the first output is coupled to the balanced structure;
wherein the second impedance matching element comprises a second balun comprising an unbalanced structure and a balanced structure,
wherein the second input is coupled to the unbalanced structure and the second output is coupled to the balanced structure.

7. The impedance matching circuit of claim 6,
wherein the balanced structure of the first balun is configured to electro-magnetically couple the unbalanced structure of the first balun at a first predefined length of the balanced structure of the first balun; and
wherein the balanced structure of the second balun is configured to electro-magnetically couple the unbalanced structure of the second balun at a second predefined length of the balanced structure of the second balun.

8. The impedance matching circuit of claim 6,
wherein the unbalanced structure of the first balun comprises a first unbalanced component with a first predefined length and a second unbalanced component with a second predefined length; and
wherein the balanced structure of the first balun comprises a first balanced component with the first predefined length and a second balanced component with the second predefined length; and
wherein the first predefined length is different than the second predefined length.

9. The impedance matching circuit of claim 8,
wherein the first predefined length of the balanced structure of the first balun is equal to the second predefined length of the balanced structure of the second balun.

10. The impedance matching circuit of claim 6,
wherein the unbalanced structure of the second balun comprises a first unbalanced component with a first predefined length and a second unbalanced component with a second predefined length; and
wherein the balanced structure of the second balun comprises a first balanced component with the first predefined length and a second balanced component with the second predefined length; and
wherein the first predefined length is different than the second predefined length.

11. The impedance matching circuit of claim 6,
wherein the first output terminal and the second output terminal of the first output comprise a differential output of the balanced structure of the first balun; and
wherein the first output terminal and the second output terminal of the second output comprise a differential output of the balanced structure of the second balun.

12. The impedance matching circuit of claim 6,
wherein the first unbalanced component of the unbalanced structure of the first balun is coupled to the first input, and the second unbalanced component of the unbalanced structure of the first balun is coupled to the ground; and
wherein the first unbalanced component of the unbalanced structure of the second balun is coupled to the second input, and the second unbalanced component of the unbalanced structure of the second balun is coupled to the ground.

13. The impedance matching circuit of claim 3,
wherein the first impedance matching element comprises a first transformer balun comprising a primary winding and a secondary winding;
wherein the second impedance matching element comprises a second transformer balun comprising a primary winding and a secondary winding;
wherein the first input comprises a first input terminal and a second input terminal;
wherein the first input terminal and the second input terminal of the first input are coupled to the primary winding of the first transformer balun;
wherein the second input comprises a first input terminal and a second input terminal;
wherein the first input terminal and the second input terminal of the second input are coupled to the primary winding of the second transformer balun;
wherein the secondary winding of the first transformer balun is coupled to the first output terminal and the second output terminal of the first output; and
wherein the secondary winding of the second transformer balun is coupled to the first output terminal and the second output terminal of the second output.

14. The impedance matching circuit of claim 13, further comprising:
a third impedance matching element comprising a third transformer balun comprising a primary winding and a secondary winding;
wherein the primary winding of the third transformer balun is coupled to the first input in a parallel configuration; and
wherein the secondary winding of the third transformer is coupled to the first output and the second output in a series configuration.

15. The impedance matching circuit of claim 13, further comprising
an impedance matching circuit input coupled to a first signal path at which the primary winding of the first transformer balun, the primary winding of the second transformer balun, and the primary winding of the third transformer balun are coupled in parallel,
an impedance matching circuit output comprising two terminals coupled at a second signal path at which the secondary winding of the first transformer balun, the secondary winding of the second transformer balun, and the secondary winding of the third transformer balun are connected in series; and
wherein the output impedance of the impedance matching circuit is nine times the impedance of the impedance matching circuit input.

16. The impedance matching circuit of claim 13, further comprising
a plurality of impedance matching elements, wherein each of the plurality of impedance matching elements comprising a transformer balun comprising a primary winding and a secondary winding; and
wherein the primary winding of each of the plurality of impedance matching elements are coupled to the first input in parallel, and the secondary winding of each of the plurality of impedance matching elements are coupled to the first output and the second output in series.

17. An impedance matching element comprising:
a first conductor configured to
receive an unbalanced input signal, and
couple the unbalanced input signal electro-magnetically to a second conductor over a first predefined length of the second conductor;
a third conductor electrically coupled to the first conductor, the third conductor configured to couple the unbalanced input signal electro-magnetically to a fourth conductor over a second predefined length of the fourth conductor, wherein the second predefined length is different from the first predefined length.

18. The impedance matching element of claim 17,
wherein the second conductor is configured to provide an output of a first balanced signal, and
wherein the fourth conductor is configured to provide an output of a second balanced signal.

19. An impedance matching circuit comprising:
a first transformer comprising a first primary winding and a first secondary winding, wherein the first primary winding has a first primary impedance, and the first secondary winding has a second primary impedance;
a second transformer comprising a second primary winding and a second secondary winding, wherein the second primary winding has a first primary impedance, and the second secondary winding has a second secondary impedance; wherein the second primary winding is coupled to the first primary winding in parallel, and the coupling of the first primary winding and the second primary winding matches an input impedance of the impedance matching circuit; and
wherein the second secondary winding and the second primary winding are coupled in series, wherein the coupling of the first secondary winding and the second secondary winding matches an output impedance of the impedance matching circuit.

20. The impedance matching circuit of claim 19,
wherein the impedance matching circuit comprises a number N of a plurality of transformers comprising the first transformer and the second transformer; and
wherein the output impedance of the impedance matching circuit has an impedance substantially N² times the input impedance of the impedance matching circuit.
